(19) United States
(12) Patent Application Publication
(10) Pub. No.: US 2024/0038808 A1
(43) Pub. Date: Feb. 1, 2024

(54) SOLID-STATE IMAGING DEVICE AND ELECTRONIC APPARATUS

(71) Applicant: SONY SEMICONDUCTOR SOLUTIONS CORPORATION, Kanagawa (JP)

(72) Inventor: Sumie TANOUE, Kanagawa (JP)

(73) Assignee: SONY SEMICONDUCTOR SOLUTIONS CORPORATION, Kanagawa (JP)

(21) Appl. No.: 18/258,353

(22) PCT Filed: Dec. 9, 2021
(86) PCT No.: PCT/JP2021/045289

§ 371 Date: Jun. 20, 2023

(30) Foreign Application Priority Data
Dec. 28, 2020 (JP) 2020-219443

(51) Int. Cl. H01L 27/146

(52) U.S. Cl. CPC H01L 27/1463; H01L 27/14645; H01L 27/14683

(57) ABSTRACT

A solid-state imaging device as disclosed includes: a semiconductor substrate; a floating diffusion region; a conversion efficiency switching transistor; and a first pixel separation section. The semiconductor substrate has a first surface and a second surface that are opposed to each other. The semiconductor substrate has a photoelectric conversion section formed therein for each of the pixels. The photoelectric conversion section generates electric charge through photoelectric conversion. The electric charge corresponds to an amount of received light. The floating diffusion region is provided in the semiconductor substrate, and accumulates the electric charge generated by the photoelectric conversion section. The conversion efficiency switching transistor causes capacitance of the floating diffusion region to be variable. The first pixel separation section is provided in the semiconductor substrate and includes an electrically conductive material that separates the adjacent pixels and that is coupled to the floating diffusion region through the conversion efficiency switching transistor.

### TECHNICAL FIELD

The present disclosure relates to a solid-state imaging device that performs imaging by performing photoelectric conversion and an electronic apparatus including this solid-state imaging device.

### BACKGROUND ART

Solid-state imaging devices are each requested to have a wider dynamic range. For example, PTL 1 discloses a solid-state imaging device in which FDG is provided as a switch for switching conversion efficiency that causes capacitance of a floating diffusion (FD) to be variable and a planar MOS capacitor (FC) is further coupled to this FDG. In addition, for example, PTL 2 discloses an imaging element provided with a comb-shaped wiring line as an additional capacitor of FD in an interlayer insulating film on a silicon substrate.

### CITATION LIST

### Patent Literature

PTL 1: International Publication No. WO 2017/043343
PTL 2: Japanese Unexamined Patent Application Publication No. 2013-33896

### SUMMARY OF THE INVENTION

Incidentally, a solid-state imaging device has an issue with a degree of layout freedom of a pixel or a wiring line decreased by providing a capacitive element that is coupled to FDG.

It is desirable to provide a solid-state imaging device and an electronic apparatus that each make it possible to reduce restrictions on layouts of a pixel and a wiring line.

A solid-state imaging device according to an embodiment of the present disclosure includes: a semiconductor substrate; a floating diffusion region; a conversion efficiency switching transistor; and a first pixel separation section. The semiconductor substrate has a first surface and a second surface that are opposed to each other. The semiconductor substrate has a photoelectric conversion section formed to be buried therein for each of pixels. The photoelectric conversion section generates electric charge through photoelectric conversion. The electric charge corresponds to an amount of received light. The floating diffusion region is provided in the semiconductor substrate. The floating diffusion region accumulates the electric charge generated by the photoelectric conversion section. The conversion efficiency switching transistor causes capacitance of the floating diffusion region to be variable. The first pixel separation section is provided in the semiconductor substrate and includes an electrically conductive material. The first pixel separation section separates the adjacent pixels and is coupled to the floating diffusion region through the conversion efficiency switching transistor.

An electronic apparatus according to an embodiment of the present disclosure includes the solid-state imaging device according to the embodiment of the present disclosure described above.

The solid-state imaging device according to the embodiment of the present disclosure and the electronic apparatus according to the embodiment are each provided with the first pixel separation section having electrical conductivity between the adjacent pixels. This first pixel separation section and the conversion efficiency switching transistor are coupled through the floating diffusion region. This adds capacitance to the conversion efficiency switching transistor without providing a new element in the pixel or a wiring layer provided with a circuit.

### BRIEF DESCRIPTION OF DRAWING

FIG. 1 is a schematic diagram illustrating an example of a planar configuration of a solid-state imaging device according to an embodiment of the present disclosure.

FIG. 2 is a schematic diagram illustrating an example of a cross-sectional configuration of the solid-state imaging device illustrated in FIG. 1.

FIG. 3 is an equivalent circuit diagram illustrating a circuit configuration of the solid-state imaging device illustrated in FIG. 1.

FIG. 4 is a block diagram illustrating an overall configuration of the solid-state imaging device illustrated in FIG. 1.

FIG. 5A is a cross-sectional schematic diagram illustrating an example of a step of manufacturing a pixel separation section illustrated in FIG. 1.

FIG. 5B is a cross-sectional schematic diagram illustrating a step subsequent to FIG.

FIG. 5C is a cross-sectional schematic diagram illustrating a step subsequent to FIG.

FIG. 5D is a cross-sectional schematic diagram illustrating a step subsequent to FIG. 5C.

FIG. 5E is a cross-sectional schematic diagram illustrating a step subsequent to FIG. 5D.

FIG. 5F is a cross-sectional schematic diagram illustrating a step subsequent to FIG. 5E.

FIG. 5G is a cross-sectional schematic diagram illustrating a step subsequent to FIG. 5F.

FIG. 5H is a cross-sectional schematic diagram illustrating a step subsequent to FIG. 5G.

FIG. 5I is a cross-sectional schematic diagram illustrating a step subsequent to FIG. 5H.

FIG. 5J is a cross-sectional schematic diagram illustrating a step subsequent to FIG. 5I.

FIG. 6 is a schematic diagram illustrating an example of a planar configuration of a solid-state imaging device according to a modification example 1 of the present disclosure.

FIG. 7 is an equivalent circuit diagram illustrating a circuit configuration of the solid-state imaging device illustrated in FIG. 6.

FIG. 8A is a plane schematic diagram illustrating another example of a layout of the pixel separation section.

FIG. 8B is a plane schematic diagram illustrating another example of the layout of the pixel separation section.

FIG. 9 is a schematic diagram illustrating an example of a cross-sectional configuration of a solid-state imaging device according to a modification example 2 of the present disclosure.

FIG. 10 is a schematic diagram illustrating an example of a cross-sectional configuration of a solid-state imaging device according to a modification example 3 of the present disclosure.

FIG. 11 is a schematic diagram illustrating an example of a cross-sectional configuration of a solid-state imaging device according to a modification example 4 of the present disclosure.

FIG. 12 is a schematic diagram illustrating an example of a cross-sectional configuration of a solid-state imaging device according to a modification example 5 of the present disclosure.

FIG. 13 is a block diagram illustrating a configuration example of an electronic apparatus including the solid-state imaging device illustrated in FIG. 4.

FIG. 14 is a view depicting an example of a schematic configuration of an endoscopic surgery system.

FIG. 15 is a block diagram depicting an example of a functional configuration of a camera head and a camera control unit (CCU).

FIG. 16 is a block diagram depicting an example of schematic configuration of a vehicle control system.

FIG. 17 is a diagram of assistance in explaining an example of installation positions of an outside-vehicle information detecting section and an imaging section.

### MODES FOR CARRYING OUT THE INVENTION

The following describes an embodiment of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.

### 1. Embodiment (Example of Solid-state Imaging Device Including Pixel Separation Section Including Electrically Conductive Material and Electrically Coupled to Conversion Efficiency Switching Transistor)

### 1-1. Configuration of Solid-State Imaging Device

### 1-2. Method of Manufacturing Pixel Separation Section

### 1-3. Workings and Effects

### 2. Modification Examples

### 2-1. Modification Example 1 (Another Example of Structure of Pixel Separation Section)

### 2-2. Modification Example 2 (Another Example of Structure of Pixel Separation Section)

### 2-3. Modification Example 3 (Another Example of Structure of Pixel Separation Section)

### 2-4. Modification Example 4 (Another Example of Structure of Pixel Separation Section)

### 2-5. Modification Example 5 (Another Example of Structure of Pixel Separation Section)

### 3. Application Example

### 4. Practical Application Examples

### 1. Embodiment

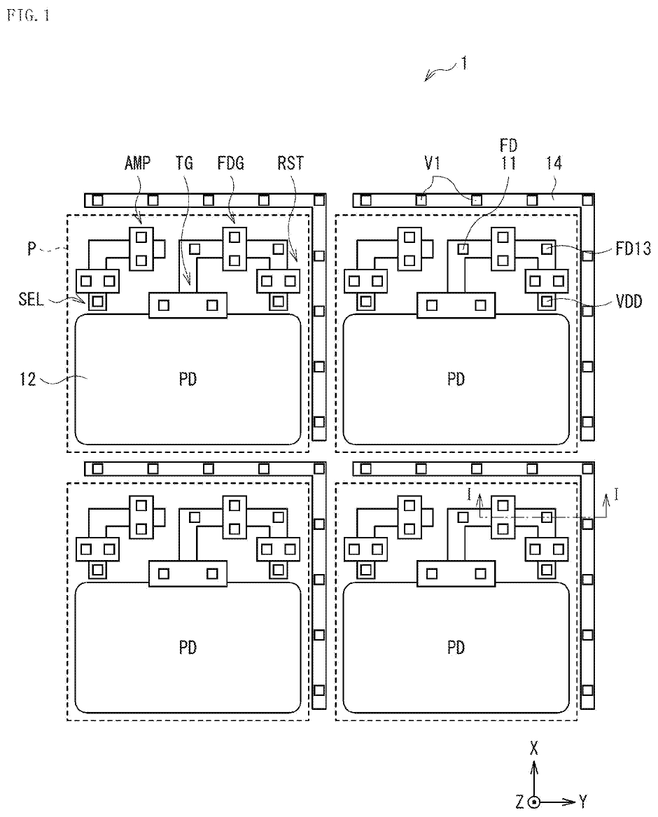

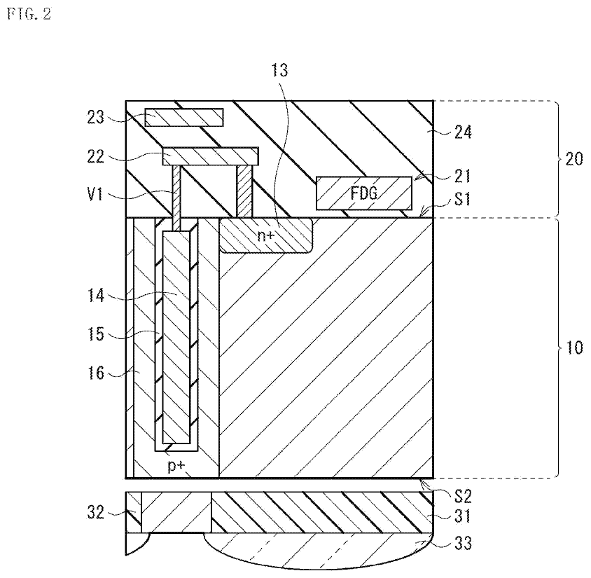

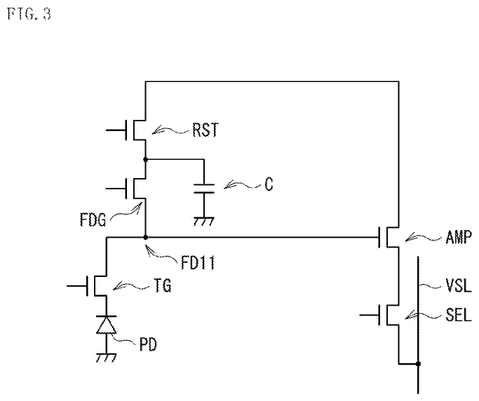

FIG. 1 schematically illustrates an example of a planar configuration of a solid-state imaging device (solid-state imaging device 1) according to an embodiment of the present disclosure. FIG. 2 schematically illustrates an example of a cross-sectional configuration of the solid-state imaging device 1 taken along an I-I line illustrated in FIG. 1. FIG. 3 illustrates an example of an equivalent circuit of the solid-state imaging device 1 illustrated in FIG. 1. The solid-state imaging device 1 captures an image by receiving light from an object, photoelectrically converting the light, and generating an image signal. The solid-state imaging device 1 is, for example, a so-called back-illuminated image sensor such as a CMOS (Complementary Metal Oxide Semiconductor) image sensor.

The back-illuminated image sensor refers to an image sensor having a configuration in which a photoelectric conversion section such as a photodiode is provided between a light receiving surface and a wiring layer (wiring layer 20). The photoelectric conversion section receives light from an object and converts the light into an electric signal. The light from the object enters the light receiving surface. The wiring layer 20 is provided with a wiring line such as a readout circuit that drives each of pixels (unit pixels P).

The solid-state imaging device 1 according to the present embodiment is provided with a pixel separation section 14 between the unit pixels P adjacent in a pixel unit 100. In addition, this pixel separation section 14 and a conversion efficiency switching transistor FDG are electrically coupled. The pixel separation section 14 includes an electrically conductive material. The plurality of unit pixels P is disposed in a matrix in the pixel unit 100 (see FIG. 4).

### [1-1. Configuration of Solid-State Imaging Device]

FIG. 4 illustrates an example of an overall configuration of the solid-state imaging device 1. As described above, the solid-state imaging device 1 is, for example, a CMOS image sensor. The solid-state imaging device 1 takes in incident light (image light) from an object through an optical lens system (not illustrated). The solid-state imaging device 1 converts the amount of incident light formed on an imaging surface as an image into electric signals in units of pixels and outputs the electric signals as pixel signals. The solid-state imaging device 1 includes the pixel unit 100 serving as an imaging area on a semiconductor substrate 10. In addition, the solid-state imaging device 1 includes, for example, a vertical drive circuit 111, a column signal processing circuit 112, a horizontal drive circuit 113, an output circuit 114, a control circuit 115, and an input/output terminal 116 in a peripheral region of this pixel unit 100.

The pixel unit 100 includes, for example, the plurality of unit pixels P that is two-dimensionally disposed in a matrix. These unit pixels P are provided, for example, with a pixel drive line Lread (specifically, a row selection line and a reset control line) for each of pixel rows and provided with a vertical signal line Lsig for each of pixel columns. The pixel drive line Lread transmits a drive signal for reading out a signal from a pixel. One end of the pixel drive line Lread is coupled to an output terminal of the vertical drive circuit 111 corresponding to each of the rows.

The vertical drive circuit 111 includes a shift register, an address decoder, and the like. The vertical drive circuit 111 is a pixel driver that drives the respective unit pixels P of the pixel unit 100, for example, in units of rows. Signals outputted from the respective unit pixels Pin the pixel rows selectively scanned by the vertical drive circuit 111 are supplied to the column signal processing circuits 112 through the respective vertical signal lines Lsig. Each of the column signal processing circuits 112 includes an amplifier, a horizontal selection switch, and the like that are provided for each of the vertical signal lines Lsig.

The horizontal drive circuit 113 includes a shift register, an address decoder, and the like. The horizontal drive circuit 113 drives the respective horizontal selection switches of the column signal processing circuits 112 in order while scanning the horizontal selection switches. This selective scanning by the horizontal drive circuit 113 outputs the signals of the respective pixels transmitted through the respective vertical signal lines Lsig to a horizontal signal line 121 in order and transmits the signals to outside of the semiconductor substrate 10 through the horizontal signal line 121.

The output circuit 114 performs signal processing on the signals sequentially supplied from the respective column signal processing circuits 112 through the horizontal signal line 121 and outputs the signals. The output circuit 114 performs, for example, only buffering in some cases and performs black level adjustment, column variation correction, various kinds of digital signal processing, and the like in other cases.

Circuit portions including the vertical drive circuit 111, the column signal processing circuits 112, the horizontal drive circuit 113, the horizontal signal line 121, and the output circuit 114 may be formed directly on the semiconductor substrate 10 or may be provided in external control IC. In addition, those circuit portions may be formed on another substrate coupled by a cable or the like.

The control circuit 115 receives a clock supplied from the outside of the semiconductor substrate 10, data for an instruction about an operation mode, and the like and also outputs data such as internal information of the solid-state imaging device 1. The control circuit 115 further includes a timing generator that generates a variety of timing signals and controls driving of peripheral circuits including the vertical drive circuit 111, the column signal processing circuits 112, the horizontal drive circuit 113, and the like on the basis of the variety of timing signals generated by the timing generator.

The input/output terminal 116 exchanges signals with the outside.

### (Circuit Configuration of Unit Pixel)

The unit pixel P includes a floating dislocation (FD) 11, a photodiode (PD) 12, and a readout circuit. The readout circuit outputs an electric signal as a pixel signal. The electric signal is based on electric charge outputted from the unit pixel P. The readout circuit includes, for example, five transistors. Specifically, the readout circuit includes a transfer transistor TG, an amplification transistor AMP, a selection transistor SEL, a reset transistor RST, and the conversion efficiency switching transistor FDG.

In the unit pixel P, for example, a cathode of the PD 12 is electrically coupled to a source of the transfer transistor TG and an anode of the PD 12 is electrically coupled to a reference potential line (e.g., ground GND). A drain of the transfer transistor TG is electrically coupled to the FD 11 and a gate of the transfer transistor TG is electrically coupled to a drive signal line. This drive signal line is a portion of the plurality of pixel drive lines Lread. The plurality of pixel drive lines Lread is coupled, for example, to the respective unit pixels P.

The transfer transistor TG transfers electric charge generated by the PD 12 to the FD 11. In a case where the transfer transistor TG is turned on, the electric charge of the PD 12 is transferred to the FD 11 through the transfer transistor TG.

The reset transistor RST includes a drain coupled to a power supply line VDD and a source coupled to FD 13. The reset transistor RST resets a potential of the FD 11 to a predetermined potential in accordance with a drive signal that is applied to a gate electrode thereof. In a case where the reset transistor RST is turned on, the potential of the FD 11 is reset to a voltage level of the power supply line VDD. In other words, the FD 11 is initialized.

The selection transistor SEL controls a timing for outputting a pixel signal. The selection transistor SEL is turned on in a case where the unit pixel P is selected. The selection transistor SEL outputs an electric signal supplied from the FD 11 through the amplification transistor AMP to the column signal processing circuit 112 through a vertical signal line VSL (Lsig).

The amplification transistor AMP outputs, as a pixel signal, an electric signal corresponding to a level of the electric charge held in the FD 11. The amplification transistor AMP is included in a source follower circuit along with a constant current source provided in the column signal processing circuit 112. In a case where the selection transistor SEL is turned on, the amplification transistor AMP amplifies the potential of the FD 11 and outputs a voltage corresponding to the potential to the column signal processing circuit 112 through the vertical signal line VSL.

The conversion efficiency switching transistor FDG is used to change a gain of electric charge-voltage conversion by the FD 11. In general, a pixel signal is small in shooting in a dark place (low illuminance). In a case where the FD 13 has large capacitance (FD capacitance C) in electric charge-voltage conversion, conversion to a voltage by the amplification transistor AMP causes V to be small on the basis of Q=CV. In contrast, a pixel signal is large in a bright place (high illuminance). Thus, unless the FD capacitance C is large, the FD 13 fails in receiving the electric charge of the PD 12. Further, the FD capacitance C has to be large to prevent V from being too large (i.e., to make V small) in a case of conversion to a voltage by the amplification transistor AMP. If these are taken into consideration, diffusion layer capacitance for the conversion efficiency switching transistor FDG increases, or the diffusion layer capacitance and wiring capacitance increase in a case where the conversion efficiency switching transistor FDG is turned on. This increases the whole FD capacitance C. In contrast, in a case where the conversion efficiency switching transistor FDG is turned off, the whole FD capacitance C decreases. In this way, switching the conversion efficiency switching transistor FDG on and off allows the FD capacitance C to be variable. This makes it possible to switch conversion efficiency.

### (Configuration of Pixel Unit)

Next, a planar configuration and a cross-sectional configuration of the pixel unit 100 are described with reference to FIGS. 1 and 2. In the pixel unit 100, the plurality of unit pixels P is two-dimensionally disposed in an array in a row direction and a column direction. Each of the unit pixels P includes the FD 11, the PD 12, the floating diffusion (FD) 13, and the readout circuit. The PD 12 is formed to be buried in the semiconductor substrate 10. The readout circuit includes the transfer transistor TG, the amplification transistor AMP, the selection transistor SEL, the reset transistor RST, and the conversion efficiency switching transistor FDG described above. The semiconductor substrate 10 has a pair of opposed surfaces (a first surface S1 and a second surface S2). The unit pixel P further includes the wiring layer 20 on the first surface S1 side of the semiconductor substrate 10 and includes a color filter 31, a light shielding section 32, and an on-chip lens 33 on the second surface S2 side. External light enters the on-chip lens 33.

The semiconductor substrate 10 includes, for example, a single-crystal silicon substrate. The semiconductor substrate 10 includes a p-well including a p-type semiconductor region. The second surface S2 of the semiconductor substrate 10 serves as a light receiving surface that receives light passing through the on-chip lens 33 and the color filter 31 in order from an object. This first surface S1 of the semiconductor substrate 10 corresponds to a specific example of a “first surface” according to the present disclosure and this second surface S2 of the semiconductor substrate 10 corresponds to a specific example of a “second surface” according to the present disclosure.

The FD 11 and the FD 13 are each provided, for example, near the first surface S1 of the semiconductor substrate 10 as a semiconductor region having an electrical conduction type (specifically, an n type) different from that of the p-well. The FD 11 and the FD 13 are floating diffusion regions that each convert the electric charge generated by the PD 12 through photoelectric conversion to an electric signal (e.g., a voltage signal) and output the electric signal.

The PD 12 includes, for example, a PIN (Positive Intrinsic Negative) photodiode. The PD 12 has a pn junction in a predetermined region of the semiconductor substrate 10.

The transfer transistor TG, the amplification transistor AMP, the selection transistor SEL, the reset transistor RST, and the conversion efficiency switching transistor FDG are provided on the first surface S1 side of the semiconductor substrate 10.

The semiconductor substrate 10 is further provided with the pixel separation section 14 between the adjacent unit pixels P. The pixel separation section 14 has a DTI (Deep Trench Isolation) structure. The pixel separation section 14 is for optically and electrically separating the adjacent unit pixels P. For example, the plurality of pixel separation sections 14 is provided in the pixel unit 100 to be separated from each other in a plan view. Specifically, each of the pixel separation sections 14 extends, for example, from the first surface S1 toward the second surface S2 of the semiconductor substrate 10. The pixel separation section 14 is continuously provided along two adjacent sides of the unit pixels P each having, for example, a rectangular shape. The pixel separation section 14 is formed by using an electrically conductive material. Examples of the electrically conductive material include polysilicon (poly S1). In addition, the pixel separation section 14 may be formed by using, for example, a metal material such as tungsten (W) having a light shielding property.

The pixel separation section 14 according to the present embodiment is electrically coupled to the conversion efficiency switching transistor FDG, for example, through a wiring line 22 provided in the wiring layer 20. The wiring line 22 is described below. In other words, the pixel separation section 14 according to the present embodiment has a role of the FD capacitance C. The pixel separation section 14 corresponds to a specific example of a “first pixel separation section” according to the present disclosure. This makes it possible to add capacitance to the conversion efficiency switching transistor FDG without reducing layout area of the PD 12 in the unit pixel P or a wiring line included in the readout circuit.

There is provided, for example, a p-type semiconductor region 16 around the pixel separation section 14 with an insulating film 15 interposed in between. The p-type semiconductor region 16 penetrates, for example, the semiconductor substrate 10 between the first surface S1 and the second surface S2 of the semiconductor substrate 10. The p-type semiconductor region 16 extends from a side surface of the pixel separation section 14 to a bottom surface on the second surface S2 side. This p-type semiconductor region 16 corresponds to a specific example of a “first electrical conduction type region” according to the present disclosure. The insulating film 15 is formed by using, for example, silicon oxide (SiO₂). The pixel separation section 14 and the wiring line 22 are electrically coupled by a via V1. The pixel separation section 14 and the wiring line 22 may be coupled by the one via V1. It is, however, possible to reduce pullout resistance by coupling the pixel separation section 14 and the wiring line 22 with the plurality of vias V1 disposed in an array, for example, as illustrated in FIG. 1. Each of these vias V1 corresponds to a specific example of a “contact” according to the present disclosure.

The wiring layer 20 is provided with a gate wiring line 21 and the wiring lines 22 and 23 in an interlayer insulating layer 24. The gate wiring line 21 serves as each of the gates of the variety of transistors included in the readout circuit described above. The wiring lines 22 and 23 include the pixel drive line Lread, the vertical signal line Lsig (VSL), the power supply line VDD, a reference potential line VSS, and the like. Portions of the wiring lines 22 and 23 (a portion of the wiring line 22 in FIG. 2) are each used as a coupling wiring line that electrically couples the FD 13 and the pixel separation section 14 as illustrated in FIG. 2. This electrically couples the pixel separation section 14 and the conversion efficiency switching transistor FDG. The gate wiring line 21 is formed by using, for example, polysilicon. Each of the wiring lines 22 and 23 is formed by using, for example, a metal material such as copper (Cu) or aluminum (Al). The interlayer insulating layer 24 is formed by using, for example, an insulating material such as silicon oxide (SiO₂).

The color filters 31 include, for example, a red color filter that transmits light in a red wavelength range, a green color filter that transmits light in a green wavelength range, and a blue color filter that transmits light in a blue wavelength range. The color filters 31 are provided, for example, in a regular color arrangement (e.g., a Bayer arrangement) in the pixel unit 100. For example, the light shielding section 32 is provided between the adjacent unit pixels P of the color filters 31.

The on-chip lens 33 condenses light coming from the second surface S2 side of the semiconductor substrate 10 on the PD 12. The on-chip lens 33 is formed by using a high refractive index material. For example, the on-chip lens 33 is formed by using an inorganic material such as silicon oxide (SiO₂) or silicon nitride (SiN). In addition, an organic material may be used that has a high refractive index such as an episulfide-based resin, a thietane compound, or a resin thereof. A shape of the on-chip lens 33 is not particularly limited, but it is possible to use a variety of lens shapes including a hemispherical shape, a semicylindrical shape, and the like. As illustrated in FIG. 2, the on-chip lens 33 may be provided for each of the unit pixels P. Alternatively, the plurality of unit pixels P may be provided with one on-chip lens.

### [1-2. Method of Manufacturing Pixel Separation Section]

It is possible to manufacture the pixel separation section 14 illustrated in any of FIGS. 1, 2, and the like, for example, as follows.

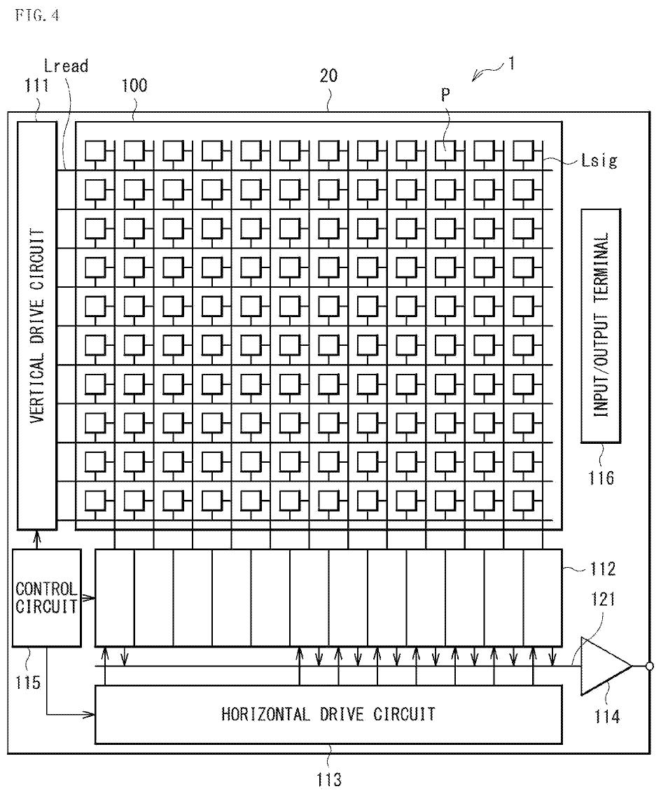

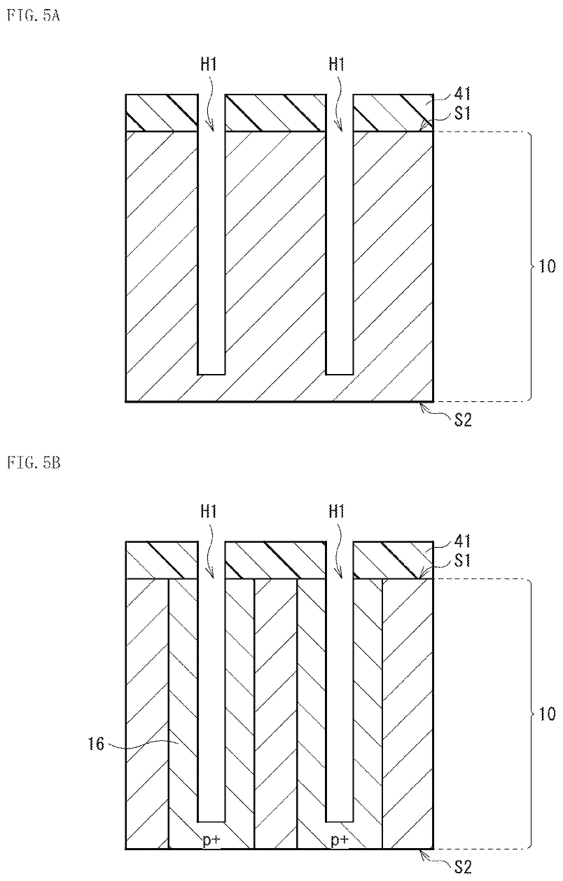

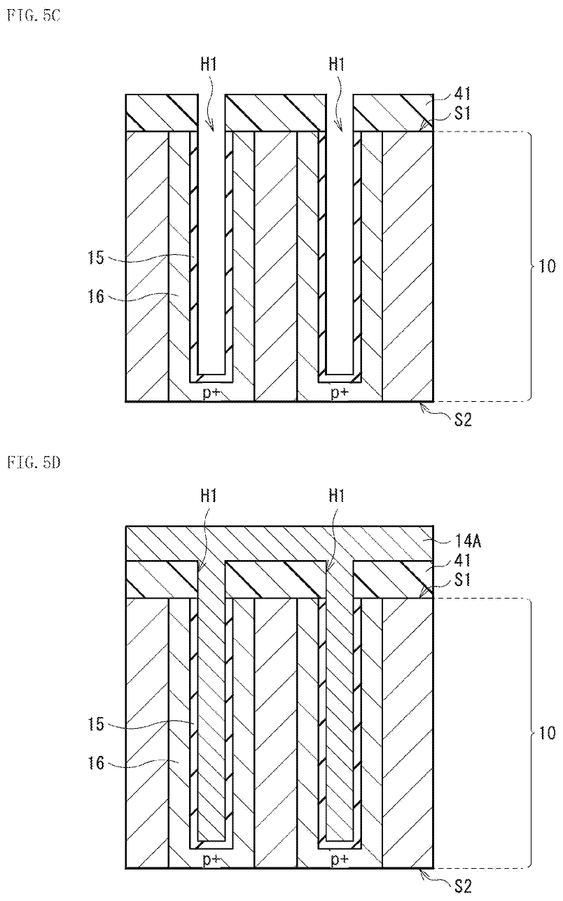

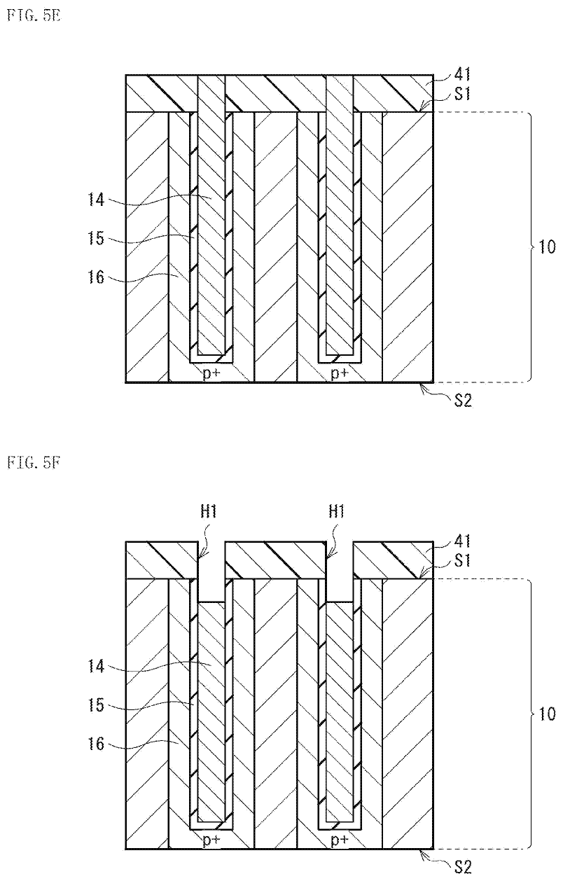

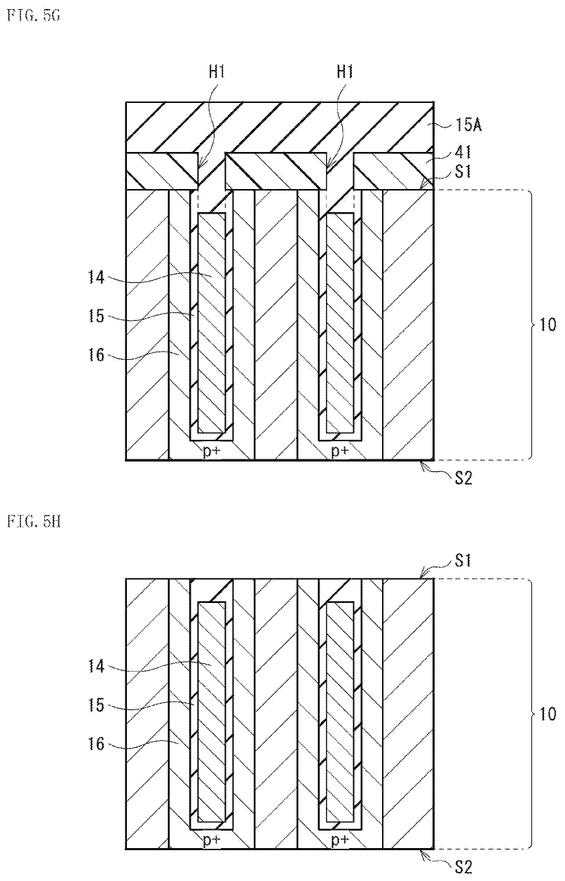

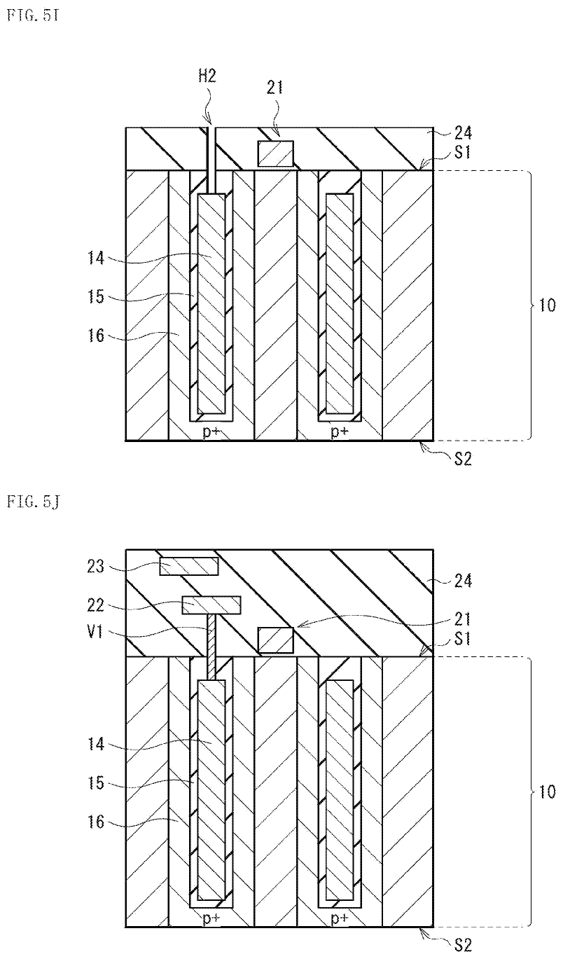

First, as illustrated in FIG. 5A, a silicon substrate is, for example, prepared as the semiconductor substrate 10. Subsequently, a mask 41 is patterned, for example, on the first surface S1 of the semiconductor substrate 10 and the semiconductor substrate 10 exposed from the mask 41 is then subjected, for example, to dry etching to form openings H1.

Subsequently, as illustrated in FIG. 5B, the p-type semiconductor regions 16 are formed in the semiconductor substrate 10 by using solid phase diffusion or plasma doping. Next, as illustrated in FIG. 5C, the insulating film 15 is formed by oxidizing a surface of the semiconductor substrate 10 in each of the openings H1. Subsequently, as illustrated in FIG. 5D, each of the openings H1 is filled with amorphous silicon by using, for example, a plasma CVD (Chemical Vapor Deposition) method. After that, for example, boron (B) ions are implanted to form a polysilicon film 14A.

Next, as illustrated in FIG. 5E, the polysilicon film 14A formed on the mask 41 is removed, for example, by chemical mechanical polishing (CMP). After that, as illustrated in FIG. each of the polysilicon films 14A in the openings H1 is etched back to a predetermined depth to form the pixel separation section 14. Subsequently, as illustrated in FIG. 5G, each of the openings H1 is filled with an insulating film 15A by using, for example, a CVD method. Next, as illustrated in FIG. 5H, the insulating film 15A on the mask 41 and the mask 41 are removed, for example, by CMP.

Subsequently, as illustrated in FIG. 5I, the gate wiring line 21 and a portion of the interlayer insulating layer 24 are formed on the first surface S1 of the semiconductor substrate 10 and an opening H2 is then formed at a predetermined position (on the pixel separation section 14). The opening H2 extends through the interlayer insulating layer 24 and the insulating film 15. Next, as illustrated in FIG. 5J, the via V1 is formed by filling the opening H2, for example, with a metal material such as Al, Cu, or W. After that, as described above, the wiring lines 22 and 23 and the interlayer insulating layer 24 are formed and the color filter 31, the light shielding section 32, and the on-chip lens 33 are then formed on the second surface S2 side of the semiconductor substrate 10. Thus, the pixel separation section 14 illustrated in any of FIGS. 1 and 2 is completed.

### [1-3. Workings and Effects]

The solid-state imaging device 1 according to the present embodiment is provided with the pixel separation section 14 between the adjacent unit pixels P. This pixel separation section 14 and the conversion efficiency switching transistor FDG are electrically coupled through the FD 13, the wiring line 22, and the via V1. The pixel separation section 14 includes an electrically conductive material. This makes it possible to add capacitance to the conversion efficiency switching transistor FDG without providing the semiconductor substrate 10 or the wiring layer 20 included in the unit pixel P with a new element. The following describes this.

As described above, solid-state imaging devices are each requested to have a wider dynamic range. Methods of widening the dynamic range include adding capacitance to the floating diffusion (FD). Examples of a method of adding capacitance include using a planar MOS capacitor, implanting a high concentration of impurities into the FD, and forming an MEM capacitor by using a wiring line.

However, in a case where a planar MOS capacitor is disposed, area of the photodiode (PD) is, for example, decreased because of an area restriction. In addition, in a case where an MEM capacitor is formed by using a wiring line, conversion efficiency may be decreased by increased wiring coupling capacitance.

In contrast, in the present embodiment, the pixel separation section 14 including an electrically conductive material is provided between the adjacent unit pixels P. This pixel separation section 14 and the conversion efficiency switching transistor FDG are coupled through the FD 13. This adds the FD capacitance C having a DTI structure and buried in the semiconductor substrate 10 to the conversion efficiency switching transistor FDG.

It is thus possible in the solid-state imaging device 1 according to the present embodiment to reduce restrictions on the layouts of the unit pixel P and the wiring line as compared with restrictions imposed in a case where a planar MOS capacitor is disposed as described above. In other words, it is possible to increase the degree of layout freedom of the unit pixel P and the wiring line.

In addition, the pixel separation section 14 having a DTI structure and buried in the semiconductor substrate 10 is used as the FD capacitance C in the solid-state imaging device 1 according to the present embodiment. This makes it possible to prevent coupling capacitance with another wiring line from increasing as compared with an increase in coupling capacitance caused by an MEM capacitor that uses a wiring line as described above. It is thus possible to achieve both high conversion efficiency in a case where the conversion efficiency switching transistor FDG is off and low conversion efficiency in a case where the conversion efficiency switching transistor FDG is on.

Further, it is possible in the solid-state imaging device 1 according to the present embodiment to easily control the capacitance value by adjusting, for example, a depth at which the pixel separation section 14 is buried.

Still further, the pixel separation section 14 functions as a light shielding film between the adjacent unit pixels P. It is thus possible to reduce occurrence of optical crosstalk.

Next, modification examples 1 to 5, an application example, and practical application examples of the present disclosure are described. The following assigns the same signs to components similar to those of the embodiment described above and omits descriptions thereof as appropriate.

### 2. MODIFICATION EXAMPLES

### 2-1. Modification Example 1

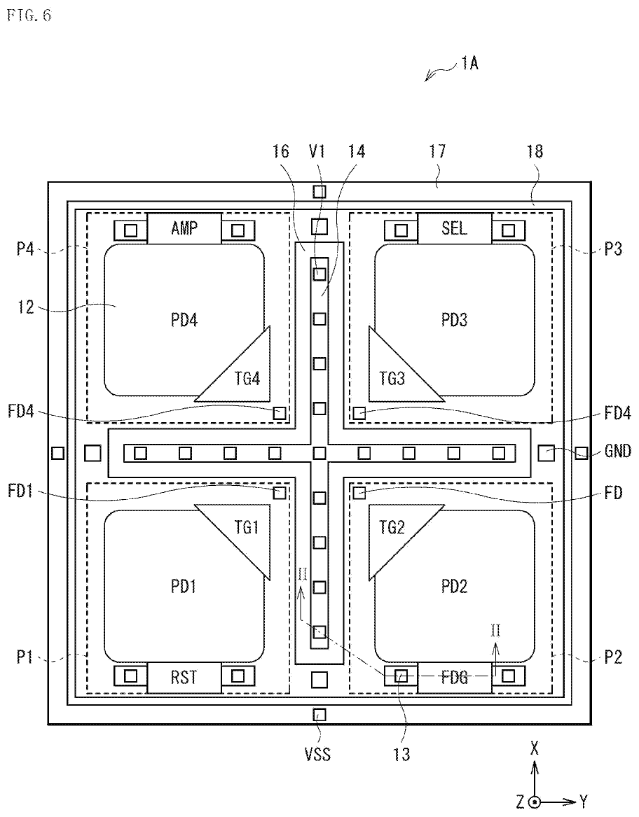

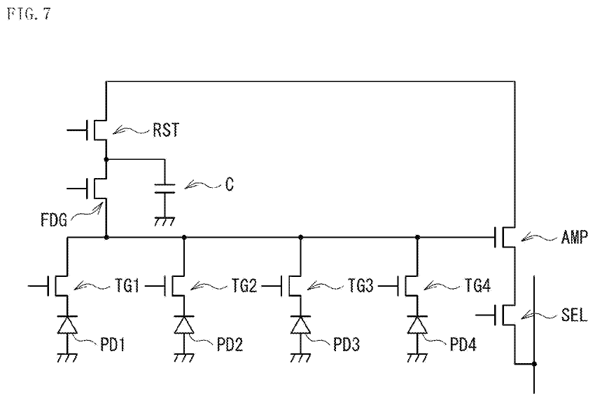

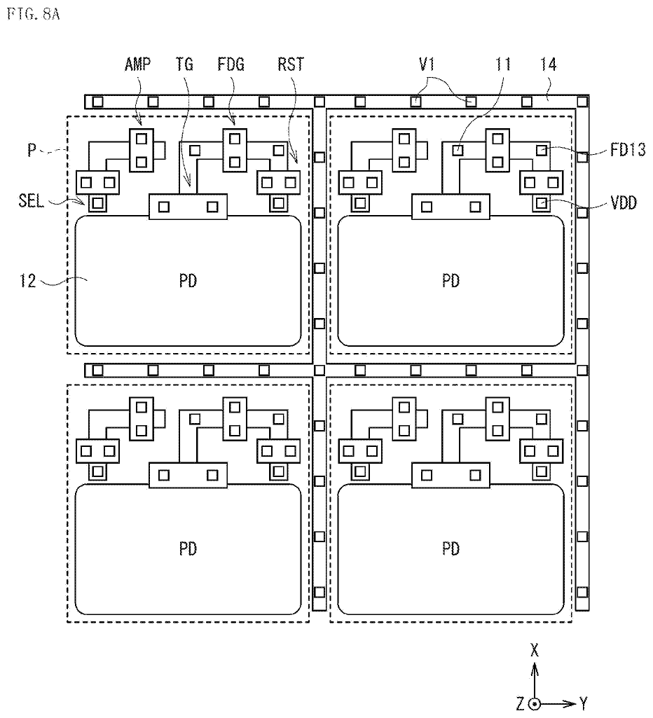

FIG. 6 schematically illustrates an example of a planar configuration of a solid-state imaging device (solid-state imaging device 1A) according to the modification example 1 of the present disclosure. FIG. 7 illustrates an example of an equivalent circuit of the solid-state imaging device 1A illustrated in FIG. 6. The present modification example is different from the embodiment described above in that a pixel sharing unit including the plurality of unit pixels P serves as a repeating unit, these pixel sharing units are repeatedly disposed in an array having the row direction and the column direction, and each of the pixel sharing units is provided with the pixel separation section 14 in the solid-state imaging device 1A according to the present modification example.

In the present modification example, a pixel sharing unit includes four unit pixels P1, P2, P3, and P4. The four unit pixels P1, P2, P3, and P4 share one floating diffusion FD. The amplification transistor AMP, the selection transistor SEL, the reset transistor RST, and the conversion efficiency switching transistor FDG included in the readout circuit are provided for each of the pixel sharing units. The four unit pixels P1, P2, P3, and P4 included in the shared pixel unit each include a common component. Each of FIGS. 6 and 7 attaches identification numbers (1, 2, 3, and 4) to ends of signs of components of the respective unit pixels P1, P2, P3, and P4 to distinguish the components of the respective unit pixels P1, P2, P3, and P4 from each other. In a case where it is necessary to distinguish the components of the respective unit pixels P1, P2, P3, and P4 from each other, the following assigns identification numbers to the ends of the signs of the components of the respective unit pixels P1, P2, P3, and P4. However, in a case where it is not necessary to distinguish the components of the respective unit pixels P1, P2, P3, and P4 from each other, the identification numbers at the ends of the signs of the components of the respective unit pixels P1, P2, P3, and P4 are omitted.

Each of the unit pixels P1, P2, P3, and P4 includes, for example, the PD 12, the transfer transistor TG electrically coupled to the PD 12, and the FD (FD 1, FD 2, FD 3, or FD 4) electrically coupled to the transfer transistor TG. A cathode of the PD 12 (PD 1, PD 2, PD 3, and PD 4) is electrically coupled to a source of the transfer transistor TG (transfer transistor TG1, TG2, TG3, or TG4). An anode of the PD 12 is electrically coupled to the reference potential line (e.g., the ground GND).

The FD 1, the FD 2, the FD 3, and the FD 4 included in the pixel sharing units are electrically coupled to each other and electrically coupled to a gate of the amplification transistor AMP and a source of the conversion efficiency switching transistor FDG. A drain of the conversion efficiency switching transistor FDG is coupled to the source of the reset transistor RST and a gate of the conversion efficiency switching transistor FDG is coupled to the drive signal line. A drain of the reset transistor RST is coupled to the power supply line VDD and a gate of the reset transistor RST is coupled to the drive signal line. The gate of the amplification transistor AMP is coupled to each of the FD 1, the FD 2, the FD 3, and the FD 4. A drain of the amplification transistor AMP is coupled to the power supply line VDD. A source of the amplification transistor AMP is coupled to a drain of the selection transistor SEL. A source of the selection transistor SEL is coupled to the vertical signal line VSL and a gate of the selection transistor SEL is coupled to the drive signal line.

The pixel separation section 14 according to the present modification example is provided, for example, in the shape of a cross as illustrated in FIG. 6 between the four unit pixels P1, P2, P3, and P4 included in the pixel sharing unit. A cross-sectional shape of the pixel separation section 14 extends between the first surface S1 and the second surface S2 of the semiconductor substrate 10 as in the embodiment described above. The p-type semiconductor region 16 is provided around the pixel separation section 14 with the insulating film 15 (not illustrated in FIG. 6) interposed in between.

In the present embodiment, there is provided a pixel separation section 17 around the pixel sharing unit. The pixel separation section 17 is independent of the pixel separation section 14. This pixel separation section 17 corresponds to a specific example of a “second pixel separation section” according to the present disclosure. The pixel separation section 17 is formed by using an electrically conductive material as with the pixel separation section 14. A cross-sectional shape of the pixel separation section 17 extends between the first surface S1 and the second surface S2 of the semiconductor substrate 10 as with the pixel separation section 14. There is provided a p-type semiconductor region 18 around the pixel separation section 17 with an insulating film (not illustrated in FIG. 6) interposed in between. A fixed potential is applied to the pixel separation section 17. The pixel separation section 17 is electrically coupled, for example, to the reference potential line VS S.

In this way, in the present modification example, each pixel sharing unit in which the one floating diffusion FD is shared between the unit pixels P1, P2, P3, and P4 is provided with the pixel separation section 14 that is electrically coupled to the conversion efficiency switching transistor FDG through the FD 13 and the wiring line (e.g., the wiring line 22). Specifically, the cross-shaped pixel separation section 14 is provided between adjacent pixels out of the four unit pixels P1, P2, P3, and P4 included in the pixel sharing unit. This pixel separation section 14 is electrically coupled to the conversion efficiency switching transistor through the FD 13 and the wiring line 22. This makes it possible to reduce the restrictions on the layouts of the unit pixel P and the wiring line. In other words, the present technology is not limited to planar layouts of the unit pixel P, the wiring line, and the pixel separation section 14, but it is possible to obtain a similar effect.

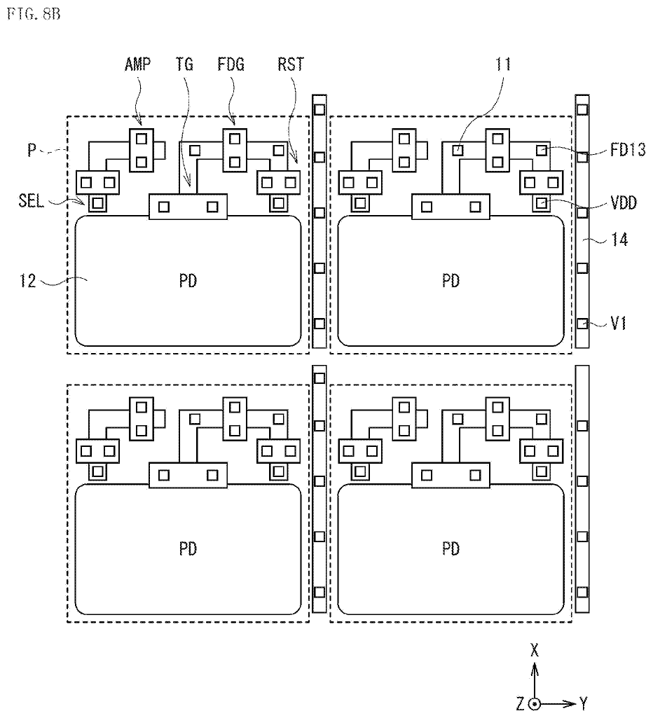

It is to be noted that the planar layouts of the pixel separation sections 14 described in the embodiment described above and the present modification example are examples. The planar layouts are not limited thereto. For example, the pixel separation section 14 may have a layout as illustrated in FIG. 8A. Alternatively, the pixel separation section 14 may be formed in only one direction (e.g., an X axis direction) as illustrated in FIG. 8B. It is, however, desirable that the pixel separation section 14 be formed to be divided into several portions in the pixel unit 100. This makes it possible to set an appropriate value for capacitance of the FD capacitance C.

### 2-2. Modification Example 2

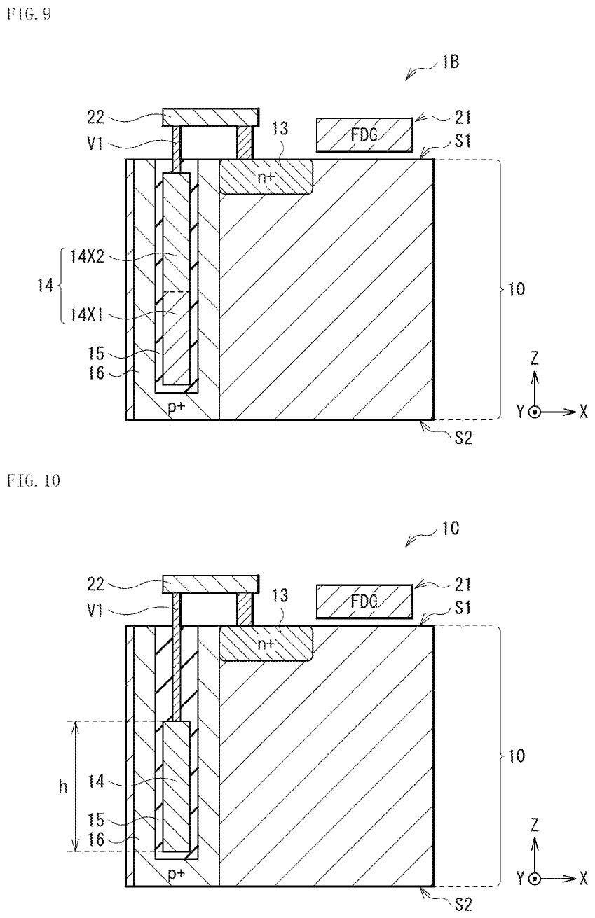

FIG. 9 schematically illustrates an example of a cross-sectional configuration of a solid-state imaging device (solid-state imaging device 1B) according to the modification example 2 of the present disclosure. The present modification example is different from the embodiment described above in that the pixel separation section 14 includes a polysilicon region 14X1 into which no impurity (ion) is implanted and a doped region 14X2 into which an ion is implanted. This polysilicon region 14X1 corresponds to a specific example of a “second region” according to the present disclosure. The doped region 14X2 corresponds to a specific example of a “first region” according to the present disclosure.

Ion implantation decreases the polysilicon in resistance. This makes it possible to adjust capacitance serving as the FD capacitance C. It is possible to adjust area of the doped region 14X2 in the pixel separation section 14 by using, for example, a dose amount, ion acceleration energy, heat treatment, and the like.

### 2-3. Modification Example 3

FIG. 10 schematically illustrates an example of a cross-sectional configuration of a solid-state imaging device (solid-state imaging device 1C) according to the modification example 3 of the present disclosure. It is possible to adjust a capacitance value of the FD capacitance C including the pixel separation section 14 by using a height (h) of an electrically conductive material (e.g., polysilicon) included in the pixel separation section 14, for example, as illustrated in FIG. 1t is possible to adjust the height of the pixel separation section 14 by controlling how much the polysilicon film 14A (see FIG. 5D) is etched back. The opening H1 is provided in the polysilicon film 14A.

The FD capacitance C is configured by using the pixel separation section 14 in this way. This makes it possible to easily control the capacitance value thereof.

### 2-4. Modification Example 4

FIG. 11 schematically illustrates an example of a cross-sectional configuration of a solid-state imaging device (solid-state imaging device 1D) according to the modification example 4 of the present disclosure. The present modification example is different from the embodiment described above in that an element separation region 19 having an STI (Shallow Trench Isolation) structure is formed on the first surface S1 of the semiconductor substrate 10 in the solid-state imaging device 1D according to the present modification example and the pixel separation section 14 is provided in this element separation region 19.

In the present modification example, the pixel separation section 14 is formed after the element separation region 19 is formed on the first surface S1 side of the semiconductor substrate 10. The p-type semiconductor region 16 provided below the element separation region 19 is formed before the element separation region 19 is formed. The insulating film 15 provided below the element separation region 19 is formed from the second surface S2 side of the semiconductor substrate 10 after the element separation region 19 and the wiring layer 20 are formed.

In this way, in the present modification example, the element separation region 19 having an STI structure is provided on the first surface S1 side of the semiconductor substrate 10 and the pixel separation section 14 is provided in the element separation region 19. This makes it possible to easily form the pixel separation section 14 as compared with the solid-state imaging device 1 according to the embodiment described above.

### 2-5. Modification Example 5

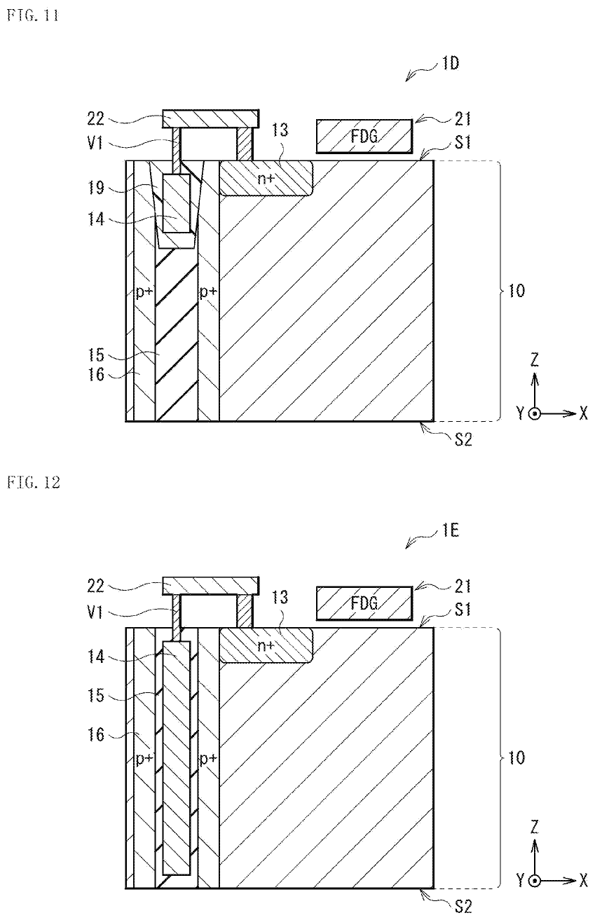

FIG. 12 schematically illustrates an example of a cross-sectional configuration of a solid-state imaging device (solid-state imaging device 1E) according to the modification example of the present disclosure. The present modification example is different from the embodiment described above in that the pixel separation section 14 having an FTI (Full Trench Isolation) structure is provided.

In the embodiment or the like described above, the example has been described in which the pixel separation section 14 is provided that has a bottom at a predetermined depth in the semiconductor substrate 10, but the pixel separation section 14 may penetrate the semiconductor substrate 10 between the first surface S1 and the second surface S2 of the semiconductor substrate

In this way, providing the pixel separation section 14 that penetrates the semiconductor substrate 10 between the first surface S1 and the second surface S2 of the semiconductor substrate 10 makes it possible to further reduce the occurrence of optical crosstalk in addition to the structure according to the embodiment described above.

It is to be noted that the present technology has been described in the embodiment or the like described above by using a back-illuminated image sensor as an example, but the present technology is also applicable to a so-called front-illuminated image sensor in which the first surface S1 of the semiconductor substrate 10 provided with the wiring layer 20 serves as a light receiving surface.

### 3. Application Example

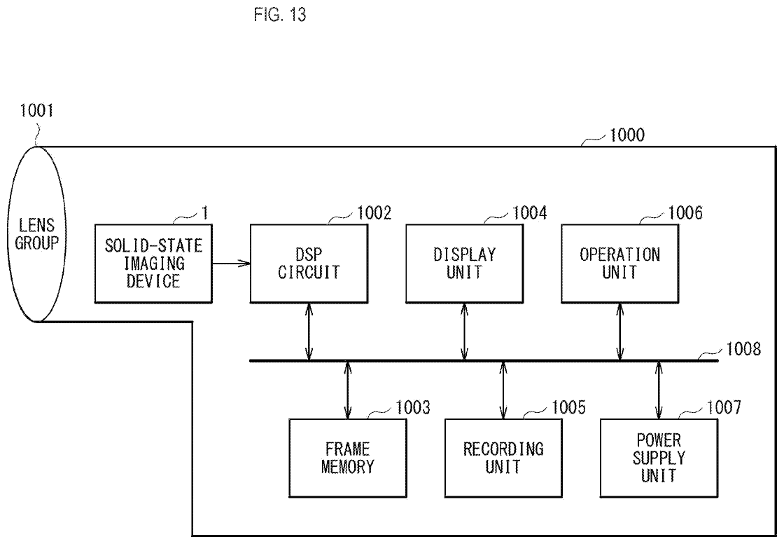

The solid-state imaging device 1 or the like described above is applicable, for example, to any type of electronic apparatus with an imaging function including a camera system such as a digital still camera or a video camera, a mobile phone having an imaging function, and the like. FIG. 13 illustrates a schematic configuration of an electronic apparatus 1000.

The electronic apparatus 1000 includes, for example, a lens group 1001, the solid-state imaging device 1, a DSP (Digital Signal Processor) circuit 1002, a frame memory 1003, a display unit 1004, a recording unit 1005, an operation unit 1006, and a power supply unit 1007. They are coupled to each other through a bus line 1008.

The lens group 1001 takes in incident light (image light) from an object and forms am image on the imaging surface of the solid-state imaging device 1. The solid-state imaging device 1 converts the amount of incident light formed as an image on the imaging surface by the lens group 1001 into electric signals in units of pixels and supplies the DSP circuit 1002 with the electric signals as pixel signals.

The DSP circuit 1002 is a signal processing circuit that processes a signal supplied from the solid-state imaging device 1. The DSP circuit 1002 outputs image data that is obtained by processing the signal from the solid-state imaging device 1. The frame memory 1003 temporarily holds the image data processed by the DSP circuit 1002 in units of frames.

The display unit 1004 includes, for example, a panel-type display device such as a liquid crystal panel or an organic EL (Electro Luminescence) panel. The display unit 1004 records image data of a moving image or a still image captured by the solid-state imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### Example of Practical Application to Endoscopic Surgery System

The technology (the present technology) according to the present disclosure is applicable to a variety of products. For example, the technology according to the present disclosure may be applied to an endoscopic surgery system.

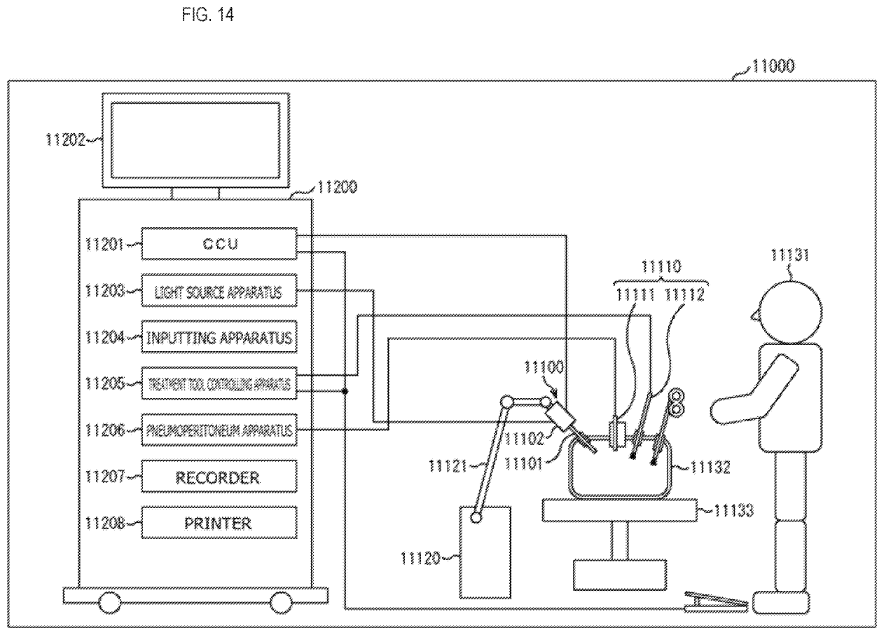

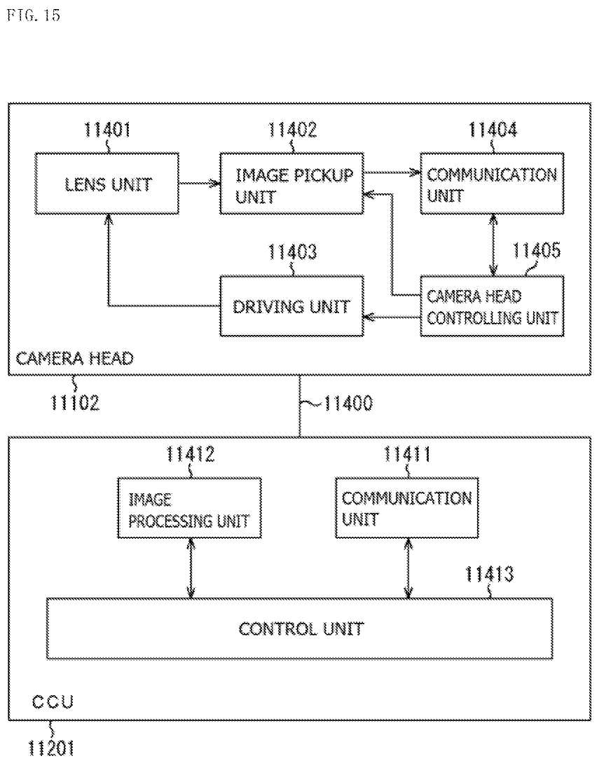

FIG. 14 is a view depicting an example of a schematic configuration of an endoscopic surgery system to which the technology according to an embodiment of the present disclosure (present technology) can be applied.

In FIG. 14, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 15 is a block diagram depicting an example of a functional configuration of the camera head 11102 and the CCU 11201 depicted in FIG. 14.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure may be applied has been described above. The technology according to the present disclosure may be applied to the image pickup unit 11402 among the components described above. The application of the technology according to the present disclosure to the image pickup unit 11402 increases heat resistance.

It is to be noted that the endoscopic surgery system has been described here as an example, but the technology according to the present disclosure may be additionally applied, for example, to a microscopic surgery system or the like.

### Example of Practical Application to Mobile Body

The technology according to the present disclosure is applicable to a variety of products.

For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

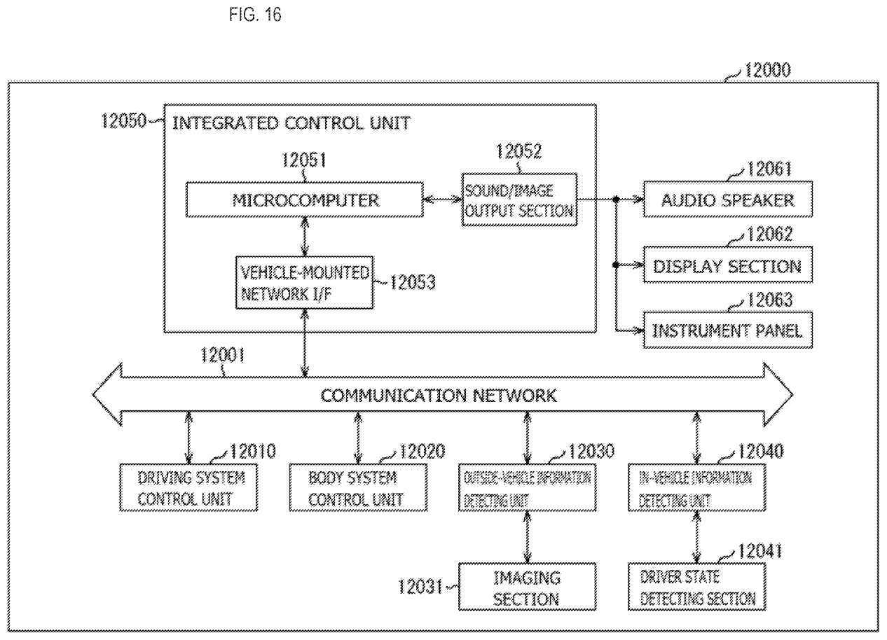

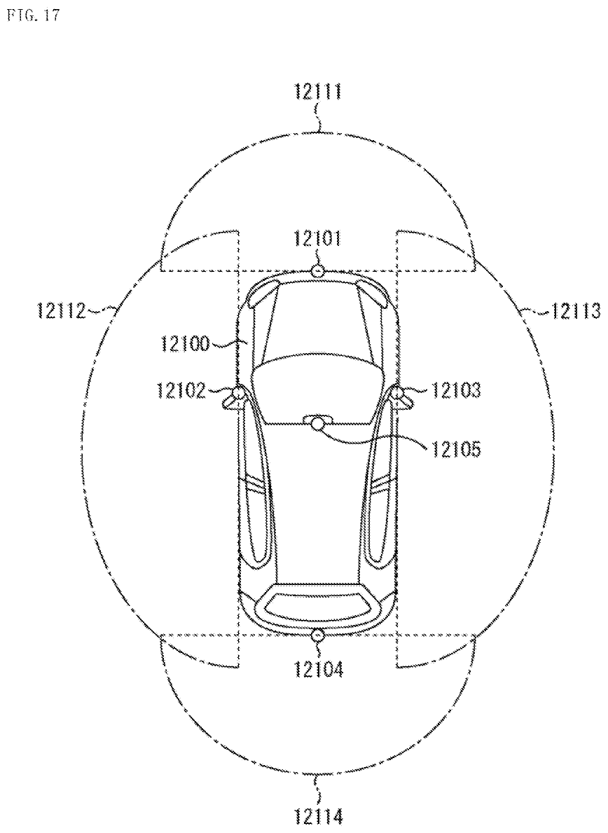

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (FF) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

FIG. 17 is a diagram depicting an example of the installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure may be applied has been described above. The technology according to the present disclosure may be applied to the imaging section 12031 among the components described above. Specifically, the solid-state imaging device 1 or the like illustrated in FIG. 1 or the like is applicable to the imaging section 12031. The application of the technology according to the present disclosure to the imaging section 12031 makes it possible to expect an excellent operation of the vehicle control system.

Although the present disclosure has been described above with reference to the embodiment, the modification examples 1 to 5, the application example, and the practical application examples, the present disclosure is not limited to the embodiment or the like described above. A variety of modifications are possible. For example, the solid-state imaging device according to the present disclosure does not have to include all of the respective components described in the embodiment or the like described above and may include another layer, conversely.

It is to be noted that the effects described herein are merely examples, but not limited to the description. There may be other effects.

It is to be noted that the present disclosure may also have configurations as follows. According to the present technology having the following configurations, the first pixel separation section having electrical conductivity is provided between the adjacent pixels. This first pixel separation section and the conversion efficiency switching transistor are coupled through the floating diffusion region. Capacitance is thus added to the conversion efficiency switching transistor without providing a new element in the pixel or the wiring layer provided with the circuit. This makes it possible to reduce the restrictions on the layouts of the pixel and the wiring line.

(1)
A solid-state imaging device including:
a semiconductor substrate having a first surface and a second surface that are opposed to each other, the semiconductor substrate having a photoelectric conversion section formed to be buried therein for each of pixels, the photoelectric conversion section generating electric charge through photoelectric conversion, the electric charge corresponding to an amount of received light;
a floating diffusion region that is provided in the semiconductor substrate, the floating diffusion region accumulating the electric charge generated by the photoelectric conversion section;
a conversion efficiency switching transistor that causes capacitance of the floating diffusion region to be variable; and
a first pixel separation section that is provided in the semiconductor substrate and includes an electrically conductive material, the first pixel separation section separating the adjacent pixels and being coupled to the floating diffusion region through the conversion efficiency switching transistor.
   (2)
The solid-state imaging device according to (1), in which
the first pixel separation section extends between the first surface and the second surface of the semiconductor substrate, and
a first electrical conduction type region is provided around the first pixel separation section with an insulating film interposed in between.
   (3)
The solid-state imaging device according to (2), in which the insulating film, or the insulating film and the first electrical conduction type region extend on a bottom of the first pixel separation section on the second surface side.
   (4)
The solid-state imaging device according to (2) or (3), in which the first pixel separation section penetrates the semiconductor substrate between the first surface and the second surface of the semiconductor substrate.
   (5)
The solid-state imaging device according to any one of (1) to (4), in which the electrically conductive material includes polysilicon.
   (6)
The solid-state imaging device according to (5), in which an impurity is implanted into at least a portion of the polysilicon.
   (7)
The solid-state imaging device according to (6), in which the polysilicon includes a first region and a second region, the first region being electrically conductive, the second region being insulative.
   (8)
The solid-state imaging device according to any one of (1) to (7), in which the capacitance is controlled by using a height of the electrically conductive material between the first surface and the second surface of the semiconductor substrate.
   (9)

The solid-state imaging device according to any one of (1) to (8), in which the semiconductor substrate further includes a pixel unit in which a plurality of the pixels is disposed in a matrix, and a plurality of the first pixel separation sections is provided in the pixel unit to be separated from each other in a plan view.

(10)
The solid-state imaging device according to any one of (1) to (9), in which the pixels each have a substantially rectangular shape, and the first pixel separation section is continuously provided along at least two adjacent sides of the pixels.
   (11)
The solid-state imaging device according to any one of (1) to (10), further including a readout circuit including the conversion efficiency switching transistor, the readout circuit outputting a pixel signal based on electric charge outputted from each of the pixels.
   (12)
The solid-state imaging device according to (11), in which the semiconductor substrate includes a plurality of pixel sharing units each including a plurality of the pixels adjacent in a row direction and a column direction, the plurality of pixels sharing the one readout circuit, and the first pixel separation section is continuously provided between the plurality of pixels included in each of the pixel sharing units.
   (13)
The solid-state imaging device according to (12), in which the semiconductor substrate further includes a second pixel separation section around each of the pixel sharing units, the second pixel separation section having a fixed potential applied thereto.
   (14)
The solid-state imaging device according to any one of (11) to (13), in which the floating diffusion region is provided near the first surface of the semiconductor substrate and the readout circuit is provided on the first surface side.
   (15)
The solid-state imaging device according to any one of (1) to (14), in which the floating diffusion region and the first pixel separation section are electrically coupled through a wiring line provided on the first surface side.
   (16)
The solid-state imaging device according to (15), in which the first pixel separation section and the wiring line are coupled by one or more contacts.
   (17)
An electronic apparatus including:
a solid-state imaging device including
   a semiconductor substrate having a first surface and a second surface that are opposed to each other, the semiconductor substrate having a photoelectric conversion section formed to be buried therein for each of pixels, the photoelectric conversion section generating electric charge through photoelectric conversion, the electric charge corresponding to an amount of received light,
a floating diffusion region that is provided in the semiconductor substrate, the floating diffusion region accumulating the electric charge generated by the photoelectric conversion section,
a conversion efficiency switching transistor that causes capacitance of the floating diffusion region to be variable, and
a first pixel separation section that is provided in the semiconductor substrate and includes an electrically conductive material, the first pixel separation section separating the adjacent pixels and being coupled to the floating diffusion region through the conversion efficiency switching transistor.

This application claims the priority on the basis of Japanese Patent Application No. 2020-219443 filed with Japan Patent Office on Dec. 28, 2020, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A solid-state imaging device comprising:
a semiconductor substrate having a first surface and a second surface that are opposed to each other, the semiconductor substrate having a photoelectric conversion section formed to be buried therein for each of pixels, the photoelectric conversion section generating electric charge through photoelectric conversion, the electric charge corresponding to an amount of received light;
a floating diffusion region that is provided in the semiconductor substrate, the floating diffusion region accumulating the electric charge generated by the photoelectric conversion section;
a conversion efficiency switching transistor that causes capacitance of the floating diffusion region to be variable; and
a first pixel separation section that is provided in the semiconductor substrate and includes an electrically conductive material, the first pixel separation section separating the adjacent pixels and being coupled to the floating diffusion region through the conversion efficiency switching transistor.

2. The solid-state imaging device according to claim 1, wherein
the first pixel separation section extends between the first surface and the second surface of the semiconductor substrate, and
a first electrical conduction type region is provided around the first pixel separation section with an insulating film interposed in between.

3. The solid-state imaging device according to claim 2, wherein the insulating film, or the insulating film and the first electrical conduction type region extend on a bottom of the first pixel separation section on the second surface side.

4. The solid-state imaging device according to claim 2, wherein the first pixel separation section penetrates the semiconductor substrate between the first surface and the second surface of the semiconductor substrate.

5. The solid-state imaging device according to claim 1, wherein the electrically conductive material includes polysilicon.

6. The solid-state imaging device according to claim 5, wherein an impurity is implanted into at least a portion of the polysilicon.

7. The solid-state imaging device according to claim 6, wherein the polysilicon includes a first region and a second region, the first region being electrically conductive, the second region being insulative.

8. The solid-state imaging device according to claim 1, wherein the capacitance is controlled by using a height of the electrically conductive material between the first surface and the second surface of the semiconductor substrate.

9. The solid-state imaging device according to claim 1, wherein
the semiconductor substrate further includes a pixel unit in which a plurality of the pixels is disposed in a matrix, and
a plurality of the first pixel separation sections is provided in the pixel unit to be separated from each other in a plan view.

10. The solid-state imaging device according to claim 1, wherein
the pixels each have a substantially rectangular shape, and
the first pixel separation section is continuously provided along at least two adjacent sides of the pixels.

11. The solid-state imaging device according to claim 1, further comprising a readout circuit including the conversion efficiency switching transistor, the readout circuit outputting a pixel signal based on electric charge outputted from each of the pixels.

12. The solid-state imaging device according to claim 11, wherein
the semiconductor substrate includes a plurality of pixel sharing units each including a plurality of the pixels adjacent in a row direction and a column direction, the plurality of pixels sharing the one readout circuit, and
the first pixel separation section is continuously provided between the plurality of pixels included in each of the pixel sharing units.

13. The solid-state imaging device according to claim 12, wherein the semiconductor substrate further includes a second pixel separation section around each of the pixel sharing units, the second pixel separation section having a fixed potential applied thereto.

14. The solid-state imaging device according to claim 11, wherein the floating diffusion region is provided near the first surface of the semiconductor substrate and the readout circuit is provided on the first surface side.

15. The solid-state imaging device according to claim 1, wherein the floating diffusion region and the first pixel separation section are electrically coupled through a wiring line provided on the first surface side.

16. The solid-state imaging device according to claim wherein the first pixel separation section and the wiring line are coupled by one or more contacts.

17. An electronic apparatus, comprising:
a solid-state imaging device including a semiconductor substrate having a first surface and a second surface that are opposed to each other, the semiconductor substrate having a photoelectric conversion section formed to be buried therein for each of pixels, the photoelectric conversion section generating electric charge through photoelectric conversion, the electric charge corresponding to an amount of received light,
a floating diffusion region that is provided in the semiconductor substrate, the floating diffusion region accumulating the electric charge generated by the photoelectric conversion section,
a conversion efficiency switching transistor that causes capacitance of the floating diffusion region to be variable, and
a first pixel separation section that is provided in the semiconductor substrate and includes an electrically conductive material, the first pixel separation section separating the adjacent pixels and being coupled to the floating diffusion region through the conversion efficiency switching transistor.
